(19) United States
(12) Patent Application Publication
(10) Pub. No.: US 2026/0005010 A1
(43) Pub. Date: Jan. 1, 2026

(54) WAFER PRODUCING METHOD

(71) Applicant: DISCO HI-TEC EUROPE GmbH, Munich (DE)

(72) Inventors: Karl Heinz PRIEWASSER, Munich (DE); Christoph EPPLE, Munich (DE)

(21) Appl. No.: 19/252,398

(22) Filed: Jun. 27, 2025

(30) Foreign Application Priority Data
Jun. 28, 2024 (DE) 10 2024 118 365.9

(51) Int. Cl. H01L 21/02

(52) U.S. Cl. CPC H01L 21/02021; H01L 21/02013; H01L 21/02016

(57) ABSTRACT

The present disclosure relates to a substrate processing method for processing a substrate having a front side and a back side. A device area is formed on the front side of the substrate. The method comprises the steps of applying a protective sheeting to the front side of the substrate, processing the protective sheeting and the substrate from the front side using a cutting device to form a circumferential wherein at edge, the circumferential edge the processed protective sheeting and the processed substrate are flush in a thickness direction of the substrate, and applying a laser beam from the back side of the substrate to form a modified layer inside the substrate in a predetermined depth.

### TECHNICAL FIELD

The present invention relates to a substrate processing method for processing a substrate.

### BACKGROUND OF THE INVENTION

In recent years the demand for smaller electronic devices (e.g., chips) constantly grew. These are particularly used in phones and other mobile equipment. In response to this demand, semiconductor substrates such as wafers with integrated circuits (ICs, LSIs) formed on a front side thereof became thinner in design.

This reduction in thickness has been achieved by grinding down wafers from their back side before dicing the wafers into single device chips. However, the rather extensive grinding process applied to achieve the target thickness resulted in a waste of wafer material, an increase in grinding time, an increased wear of the grinding tool (e.g., abrasive grinding wheels), and a higher occurrence of damage to the electronic devices such as chipping and cracks.

Such damage has particularly been observed at the outermost circumferential edge (in the following referred to as “peripheral edge”) where the wafers are generally chamfered or rounded to prevent damage to the wafers during handling. However, when such a wafer is ground to a smaller thickness, the chamfered or rounded peripheral edge of the wafer is inherently modified to have a cross-section like a knife edge, which tends to chip off and cause breakage of the wafer.

More recently, power devices such as inverters or converters came into focus of the semiconductor industry. These devices are also manufactured by dividing a wafer on which a large number of power devices are formed on a front surface into regions each including the individual power device. For these devices, silicon carbide (Sic) has been found to be the next-generation material due to its durability and higher performance comparing to silicon (Si). However, the hardness of silicon carbide is comparatively high. For this reason, various problems may occur during manufacturing chips. For example, when a wafer composed of silicon carbide is ground by a grinding apparatus, the amount of grinding wheel wear is increased so that there is a need to frequently replace the abrasive wheels. As a result, the manufacturing efficiency of such chips decreases and the manufacturing costs are increased.

JP 2007-152 906 A addressed above-described challenges by applying a wafer processing method in which the chamfered outer circumferential edge of a wafer is partly removed with a cutting blade (a so-called edge trimming step), followed by grinding the reverse side of the wafer until the thickness of the wafer becomes a finished thickness for devices to be fabricated from the wafer. Although this technique has shown to mitigate the risk of damaging the wafer, it still requires a rather extensive grinding process.

### SUMMARY OF THE DISCLOSURE

Accordingly, it has been an objective of the present disclosure to provide a substrate processing method that reduces the amount of grinding to achieve a target thickness for devices to be produced as well as their susceptibility to be damaged during processing.

This disclosure addresses this objective with a substrate processing method for processing a substrate having a front side and a back side, wherein a device area is formed on the front side of the substrate. The method comprises applying a protective sheeting to the front side of the substrate, processing the protective sheeting and the substrate from the front side using a cutting device to form a circumferential edge, wherein at the circumferential edge the processed protective sheeting and the processed substrate are flush in a thickness direction of the substrate, and applying a laser beam from the back side of the substrate to form a modified layer inside the substrate in a predetermined depth.

The substrate has a front side and a back side and may have a rounded or chamfered surrounding outer edge connecting the front side and the back side. Taking the rounded or chamfered surrounding edge into account, the substrate may generally have a cylindrical shape.

The protective sheeting is for protecting the device area (i.e., the devices of the device area) from being damaged during processing (for example, during cutting or grinding the substrate), from being contaminated with the material removed from the substrate during processing, or with the cooling or cleaning water supplied during cutting or grinding steps.

The protective sheeting comprises at least one layer and is mounted to the front side of the substrate with or without the use of an adhesive.

If an adhesive is used, the protective sheeting is preferably applied using the adhesive at least or only in a peripheral marginal area of the front side of the substrate surrounding the device area. In other words, the protective sheeting may be applied with the protective sheeting and the front side of the substrate being free of an adhesive at least in a central surface region thereof (in particular, where the device area is formed).

This way of using an adhesive has the advantage to prevent residues of the adhesive from sticking to the device area after the workpiece (at least comprising the substrate and the protective sheeting) has been processed and the protective sheeting has been removed.

Nonetheless, an adhesive may also be applied between the protective sheeting and the substrate so that the adhesive essentially covers and attaches the protective sheeting to the entire front side of the substrate.

The protective sheeting may be applied by a pressing pad (or a pressing membrane or a roller), in a vacuum environment (i.e., using a vacuum chamber) and/or by applying heat.

With the protective sheeting applied to the substrate, the processing step processes the substrate from the front side using a cutting device. The cutting device may be a laser for ablating a part of the protective sheeting and the substrate, a grinding tool (e.g. a grinding wheel), and/or a dicing tool (e.g. an abrasive dicing blade). The part of the protective sheeting and the substrate is removed to form a circumferential edge defining or surrounding a central region on the front side of the substrate that includes the device area. The circumferential edge surrounds the central region and extends in a thickness direction of the substrate. In other words, the circumferential edge is formed by a surface surrounding a central part of the substrate and facing outwards.

The circumferential edge includes the protective sheeting and the substrate after processing. In other words, a part of the circumferential edge in the thickness direction is formed by the processed protective sheeting and another part adjacent thereto is formed by the processed substrate. The surfaces of these parts are essentially flush (i.e., they form a continuous surface).

This processing step prepares for separating a substrate layer from the substrate so that it has instead of a sharp edge a duller circumferential edge (e.g., a corner of preferably about) 90°. Without processing, the rounded or chamfered surrounding edge of the substrate causes a substrate layer to have a sharp edge after being separated, particularly when the separated substrate layer is very thin. Such a sharp edge makes it harder to handle the substrate layer and is prone to be damaged, for example by chipping or cracking. Further, applying the protective sheeting beforehand to the substrate protects the device area from being contaminated by residues generated during the processing step.

Applying a laser beam from the back side of the substrate and forming a modified layer by focusing the laser beam inside the substrate provides the substrate with a separation plane that allows for detaching a substrate layer from the substrate with a thickness extending from the front side of the substrate to the separation plane.

The circumferential edge may extend partially in a thickness direction of the substrate along a distance of at least a thickness of a substrate layer to be separated from the substrate.

The circumferential edge extending in the thickness direction along the distance of at least the thickness of the substrate layer to be separated provides a basis for the substrate layer having an enhanced outer circumferential edge that is neither affected by an increased unevenness in the modified layer nor by a sharp edge caused by dividing the rounded or chamfered surrounding edge of the substrate when the substrate layer is separated from the substrate.

Processing the protective sheeting may include removing an outer part or section of the processed protective sheeting and the substrate so that the circumferential edge forms an outer peripheral edge of the protective sheeting and an outer peripheral edge of the substrate.

The outer part to be removed particularly extends in a transverse direction of the substrate from the (initial) outer surrounding edge of the substrate to the circumferential edge created during processing of the protective sheeting and the substrate. The outer part to be removed may be annular or ring-shaped.

Accordingly, the circumferential edge resulting from the processing step forms outer peripheral edges of the protective sheeting and the substrate that are flush with each other.

As an alternative to remove the outer part of the substrate, processing the protective sheeting to form the circumferential edge may include cutting a groove into the substrate to form the circumferential edge.

Thus, instead of removing the outer part of the protective sheeting and the substrate as described above, the circumferential edge generated during processing may be formed by cutting a groove into the front side of the substrate. This structures the workpiece or substrate into a central region and an outer surrounding region that are separated by the groove. The groove is preferably a ring-shaped groove and even more preferably a circular ring-shaped groove. However, other ring-shaped grooves are also envisaged (e.g. rectangular, polygonal, etc.). The groove is preferably located in the peripheral marginal area where no devices are formed.

The groove preferably has a first wall, a second wall, and a bottom connecting the first and second walls of the groove. Relative to the center of the substrate and in a transverse direction of the substrate, the first wall is an inner wall facing outwards and the second wall is an outer wall facing inwards.

The first wall corresponds to the circumferential edge that is created during processing and comprises the processed protective sheeting and the processed substrate.

The laser beam is preferably only applied in a central region of the substrate having essentially a uniform thickness (i.e., the region corresponding to or including the device area formed on the front side).

As described above, the substrate may initially have a chamfered or rounded surrounding outer edge. In this case, the thickness of the substrate decreases in a transverse outwards direction in a peripheral region of the substrate, where the chamfered or rounded edge is formed.

This varying thickness has an adverse effect on forming the modified layer within the substrate using the laser beam. More specifically, the chamfer or roundness makes it more difficult to focus the laser beam in a uniform depth due to a change in incident angle and the decreasing thickness/depth in the peripheral region of the substrate. As a result, the modified layer may be formed more uneven than in the central region of the substrate.

Preferably, the laser beam is only applied in a central region (in particular a region basically not including a chamfer or rounded edge), wherein the outline of the central region essentially corresponds to the circumferential edge formed or to be formed during the processing step of the protective sheeting and the substrate (i.e. processing the workpiece).

Inwards of the peripheral region of the substrate with a decreasing thickness (e.g., due to a chamfered or rounded edge), the thickness of the substrate is essentially uniform. Accordingly, it is possible to apply the laser beam more accurately in the central region of the substrate. Applying the laser in this manner also saves processing time and renders the creation of a modified layer within the substrate more economical.

The laser beam may be applied before or after processing the protective sheeting and the substrate.

In both cases, the laser beam is preferably (only) applied in the central region of the substrate as described above or should at least not be applied to the outermost circumference of the outer peripheral edge. If being applied before processing, the laser beam can basically be applied while avoiding any influence an interference or of outer circumferential edge (particularly a rounded or chamfered outer circumferential edge) on focusing the laser beam in the predetermined depth.

The method may further comprise pre-grinding the back side of the substrate before applying the laser beam.

Pre-grinding the back side of the substrate allows to condition the back side of the substrate for the application of the laser beam to form the modified layer. Thus, the pre-grinding step may serve to enhance the accuracy with which the modified layer is formed.

The method may further comprise separating the substrate layer from the substrate at the modified layer and preferably grinding the separation surface of the substrate and/or the separation surface of the substrate layer.

Applying the laser beam creates a modified layer, wherein the modified layer has a decreased material strength compared with the remainder of the substrate. This decrease in material strength is caused by cracks that are initiated by the energy applied at the focal point of the laser beam. Due to this change in material properties, a substrate layer may be separated along the modified layer with a higher accuracy and less material loss than with other separation methods (for example a wire saw).

Grinding of the separation surface has the advantage that on the side of the substrate layer, the strength of the substrate is enhanced due to the removal of damages or stress from the modified layer remaining on the separation surface. On the side of the remainder of the substrate, grinding may be applied to prepare the substrate for further processing (e.g. for preparing the substrate for separation of another substrate layer).

Further, the method may comprise mounting a protective sheet to the back side of the substrate after forming the modified layer inside the substrate.

The protective sheet protects the back side of the substrate, where the laser beam entered the substrate. This is particularly advantageous if a second substrate layer is to be separated from the substrate since the back side may be used without any intermediate processing after separation of the substrate layer and removal of the protective sheet to form another modified layer within the substrate. The protective sheet may also be advantageous in terms of holding the substrate on a holding table.

The protective sheet may be larger than the back side of the substrate and is attached to a ring frame surrounding the peripheral edge of the substrate at a distance.

The ring frame facilitates handling of the substrate after the laser beam has been applied.

The protective sheet may at least cover a planar surface of the back side of the substrate (i.e. the back side of the substrate except for the chamfered or rounded edge).

The substrate may be a wafer. Accordingly, the substrate processing method according to the present disclosure may serve as method for producing a thinner wafer from a wafer. Further, the remainder of the wafer may also be used to produce at least another wafer. This particularly renders the use of high-cost semiconductor materials more economical (e.g., silicon carbide).

### SHORT DESCRIPTION OF THE DRAWINGS

The following figures schematically illustrate exemplary embodiments of a processing method for a substrate according to the present disclosure. In these figures, same reference signs refer to features throughout the drawings that have the same or an equivalent function and/or structure. It is to be understood that the figures illustrate schematic examples of how the processing method is performed in accordance with the present disclosure but without limiting the invention thereto.

FIG. 1 schematically illustrates an example of a substrate layer that may be produced with the processing method according to an embodiment of the present disclosure;

FIG. 2 is a schematic partial cross-sectional view of a substrate's peripheral rounded edge illustrating the influence of the rounded edge on forming of a modified layer;

FIG. 3 is a schematic cross-sectional side view of a substrate with a protective sheeting applied to its front side;

FIG. 4 schematically depicts a grinding step for grinding the back side of the substrate shown in FIG. 3;

FIGS. 5a to 5d schematically illustrate a sequence of steps of an exemplary processing method according to a first embodiment of the present disclosure;

FIGS. 6a to 6d schematically illustrate a sequence of steps of another exemplary processing method according to a second embodiment of the present disclosure;

FIG. 7 schematically illustrates a modification of a processing step for processing the front side of the substrate including the protective sheeting; and

FIG. 8 schematically illustrates an alternative configuration for handling the substrate using a ring frame.

### DETAILED DESCRIPTION OF PREFERRED EMBODIMENTS

The substrate processing method for processing a substrate according to the present disclosure is further described in more detail below with reference to the accompanying figures. The substrate processing method is particularly directed at processing the substrate for separating a substrate layer from the substrate. It is noted that the figures are schematically illustrating various configurations of the method and that the dimensions in the drawings are exaggerated (i.e., shown bigger or smaller) for explanatory purposes.

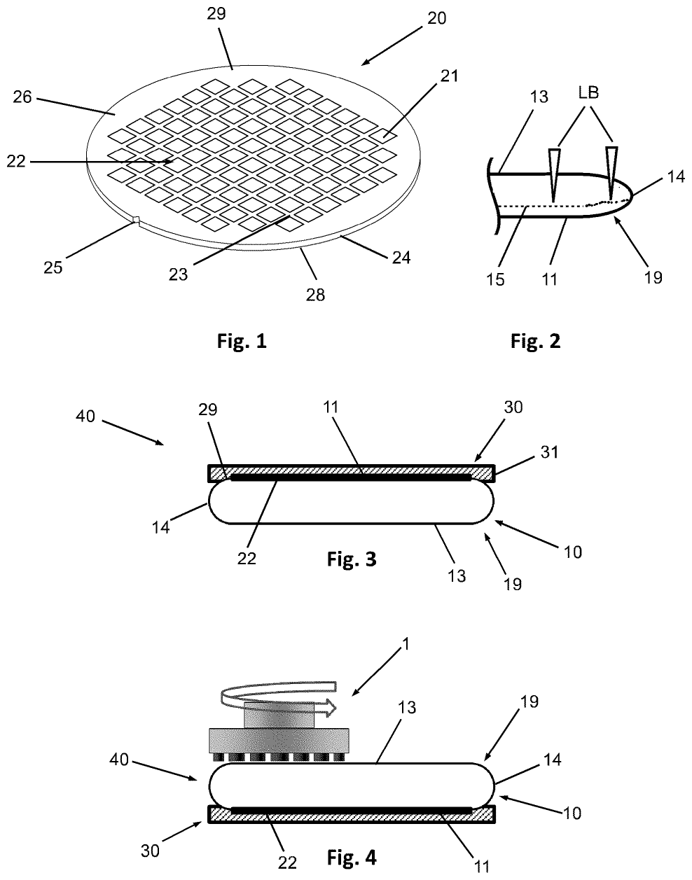

FIG. 1 schematically illustrates a substrate layer 20 that may be produced with a method according to an embodiment of the present disclosure. The substrate layer 20 is preferably a wafer. It comprises a front side 26, a back side 28, and an outer peripheral edge 24 connecting the front side 26 and the back side 28. On the front side 26, the substrate layer 20 includes a device area 22. The device area 22 includes devices 21 (for example device chips, optical devices, etc.) and is arranged in a central region of the front side 26. The devices are separated by division lines 23. Along these division lines, dicing may be performed to divide the device area 22 into single devices 21. The device area 22 is preferably surrounded by a peripheral marginal area 29, in which no devices 21 are formed.

The substrate layer 20 may comprise at least one linear section (not illustrated) or a notch 25 along its outer peripheral edge 24, which may indicate a crystal orientation.

The substrate layer 20 may result from processing a substrate 10 as partly shown in FIG. 2. More specifically, FIG. 2 is a schematic partial cross-sectional view of an outer peripheral edge 14 of a substrate 10. In the exemplary embodiment depicted in this figure, the outer peripheral edge 14 is rounded. Alternatively, the outer peripheral edge 14 may be chamfered. Such a configuration of the outer peripheral edge 14 of a substrate 10 has the advantage of avoiding a sharp edge that may otherwise result in stress concentration and damage to the substrate 10 (for example caused by chipping) during handling of the substrate 10.

However, the rounded or chamfered outer peripheral edge 14 of the substrate 10 causes a variation in thickness in an outer peripheral region 19 of the substrate 10, where the rounded or chamfered outer peripheral edge 14 is formed. More specifically, the thickness of the substrate 10 is uniform in a central region of the substrate that includes a device area 22 (see FIG. 3) but decreases in the outer peripheral region 19 of the substrate 10 due to the chamfered or rounded outer peripheral edge 14.

This configuration of the thickness at the outer peripheral edge 14 renders the creation of a modified layer 15 inside the substrate 10 more difficult, which may be caused by a changing incident angle for the laser beam LB. As for example indicated in FIG. 2, the left laser beam LB is basically oriented perpendicular to the front side 11 whereas the right laser beam LB is oriented in an oblique angle relative to the front side 11 due to the changing slope of the rounded edge. Further, the depth of the modified layer relative to the front side 11 of the substrate 10 also decreases towards the outer peripheral edge 14 of the substrate 10.

These changes tend to cause the modified layer 15 to have a less uniform depth in the outer peripheral region 19 of the substrate 10 than in a central region of the substrate that basically has a constant thickness. In other words, the modified layer 15 varies more in depth in the outer peripheral region 19 than in the central region of the substrate 10. This may in turn tend to cause a separation failure or more damage to the substrate 10 or the substrate layer 20 during its separation from the substrate 10.

Further, the outer peripheral edge 14 of the substrate 10 as well as the outer peripheral edge 24 of the substrate layer 20 after separation of the substrate layer 20 from the substrate 10 tends to be rather sharp due to the chamfered or rounded outer peripheral edge 14 of the substrate 10 before separation. This is due to sharp angles of the outer edges at the modified layer 15 that are created when separating a substrate layer 20 from the substrate 10.

The processing method according to the present disclosure has been conceived to address these adverse effects.

FIG. 3 illustrates a substrate 10 comprising a front side 11, a back side 13, and an outer peripheral edge 14. The outer peripheral edge 14 is rounded. Alternatively, the outer peripheral edge 14 may include a chamfer. On the front side 11 of the substrate 10, a device area 22 including single devices 21 is formed.

The devices in the device area 22 may be ICs (integrated circuits) and LSIs (large scale integrations). For example, the devices may be semiconductor devices, power devices, optical devices, medical devices, electrical components, MEMS devices or combinations thereof. The devices may comprise or be, for example, transistors, such as MOSFETS, insulated-gate bipolar transistors (IGBTs), or diodes, e.g., Schottky barrier diodes.

The substrate 10 may, for example, comprise semiconductor, glass, sapphire (Al2O3), ceramic, such as an alumina ceramic, quartz, zirconia, PZT (lead zirconate titanate), polycarbonate, optical crystal material or the like. In particular, the substrate may comprise silicon carbide (Sic), silicon (Si), gallium arsenide (GaAs), gallium nitride (GaN), gallium phosphide (GaP), indium arsenide (InAs), indium phosphide (InP), silicon nitride (SiN), lithium tantalate (LT), lithium niobate (LN), aluminum nitride (AlN), silicon oxide (SiO2) or the like.

The substrate may be a single crystal substrate, a glass substrate, a compound substrate, such as a compound semiconductor substrate, e.g., a Sic, SiN, GaN or GaAs substrate, or a polycrystalline substrate, such as a ceramic substrate.

As noted above, the substrate 10 may be a wafer. For example, the substrate 10 may be a semiconductor-sized wafer. Herein, the term “semiconductor-sized wafer” refers to a wafer with predetermined dimensions (standardized dimensions), in particular, the diameter (i.e., standardized diameter, outer diameter) of semiconductor a wafer. Such dimensions of semiconductor wafers are, for example, defined in the SEMI standards. For example, the dimensions of polished single crystal silicon wafers are defined in the SEMI standards M1 and M76. The semiconductor-sized wafer may be a 3 inch, 4 inch, 5 inch, 6 inch, 8 inch, 12 inch, or 18 inch wafer.

The substrate 10 is made of a single material or of a combination of different materials, e.g., two or more of the above-identified materials.

As part of the substrate processing method according to the present disclosure, a protective sheeting 30 is applied to the front side 11 of the substrate 10, which forms a workpiece 40 to be processed as will be explained in more detail below.

The application of the protective sheeting 30 is preferably performed in a vacuum (i.e. using a vacuum chamber). Further, the method may use heat during and/or after the application or lamination process.

FIG. 3 illustrates a workpiece 40 to be processed that is formed by applying a protective sheeting 30 to a front side 11 of a substrate 10. The substrate 10 comprises a front side 11 and a back side 13. The front side 11 and the back side 13 of the substrate 10 are preferably substantially parallel to each other and are substantially flat or even.

The substrate 10 is not limited to a specific shape. The substrate 10 may be cylindrical and/or plate-shaped and may comprise cross-sections with outlines that are substantially round such as oval or circular. In other words, in a top view, the substrate 10 may generally have a round shape, in particular oval or circular shape. Alternatively, the substrate 10 may have a polygonal shape such as a square or rectangular shape.

The protective sheeting 30 is applied to the front side 11 of the substrate 10 so that it at least covers the device area 22. As a result, the protective sheeting 30 protect the device area 22 during processing. In particular, the protective sheeting 30 prevents the front side 11 of the substrate 10 or the device area 22 from being contaminated with residual material removed during processing (for example, such residual material may be generated while cutting (for example by ablation, grinding or cutting) or grinding the substrate 10.

The protective sheeting 30 comprises at least one layer. Preferably, the protective sheeting 30 is configured to protect the devices 21 of the device area 22 from being contaminated and may further be configured to at least partly level out discontinuities of the surface of the front side 11 of the substrate 10. These discontinuities may particularly be caused by the device area 22 causing the side of the front side 11 having an uneven surface structure. Particularly in the latter case of leveling such a surface structure, the protective sheeting 30 may include multiple layers to enhance embedding the surface structure for providing a flat or even surface.

The protective sheeting 30 may be applied with or without the use of an adhesive arranged between the protective sheeting 30 and the side of the front side 11 of the substrate 10.

In case of using an adhesive, the adhesive is preferably (only) arranged in a portion of the protective sheeting 30 that corresponds to a peripheral marginal area 29 of the front side 11 of the substrate 10 that surrounds the device area 22 (i.e., in which no devices 21 are formed) so that the adhesive does not come in contact with the devices 21. Such a use of an adhesive prevents residues of the adhesive from remaining in the device the removal of the protective sheeting 30. It should be noted that the adhesive is preferably prearranged the on protective sheeting. Alternatively, the protective sheeting 30 and the adhesive may also be arranged one by one (separately one after the other) onto the wafer.

Nonetheless, the adhesive may also be arranged in the peripheral marginal area 29 and the device area 22 between the protective sheeting 30 and the substrate 10 so that the adhesive essentially covers and fixes the protective sheeting 30 to the entire front side 11 of the substrate 10.

Particularly without the use of an adhesive (but also with the use of an adhesive), the protective sheeting 30 may be applied by a pressing pad (or a pressing membrane or a roller), in a vacuum environment (using a vacuum chamber) and/or by applying heat.

The vacuum environment particularly serves to prevent air bubbles from being trapped in between the protective sheeting 30 and the front side 11 of the substrate 10, where the device area 22 is formed. Further, employing heat for the application of the protective sheeting 30 may enhance adaptation of the protective sheeting 30 to a surface structure of the front side 11 of the substrate 10 and in particularly to the surface structure due to the devices 21 of the device area 22. Heat may also be applied to cause the material of the protective sheeting 30 to become softer and further enhance a sealing effect (in particular in the peripheral marginal area 29 of the front side 11 of the substrate 10).

After attaching the protective sheeting 30 to the substrate 10 which forms the workpiece 40, an optional grinding step may be performed to flatten the back side 13 of the substrate 10 in order to prepare the back side 13 of the substrate 10 for the application of a laser beam LB. Such a laser beam LB may particularly be used to form a modified layer 15 inside the substrate 10 as will be described in more detail further below.

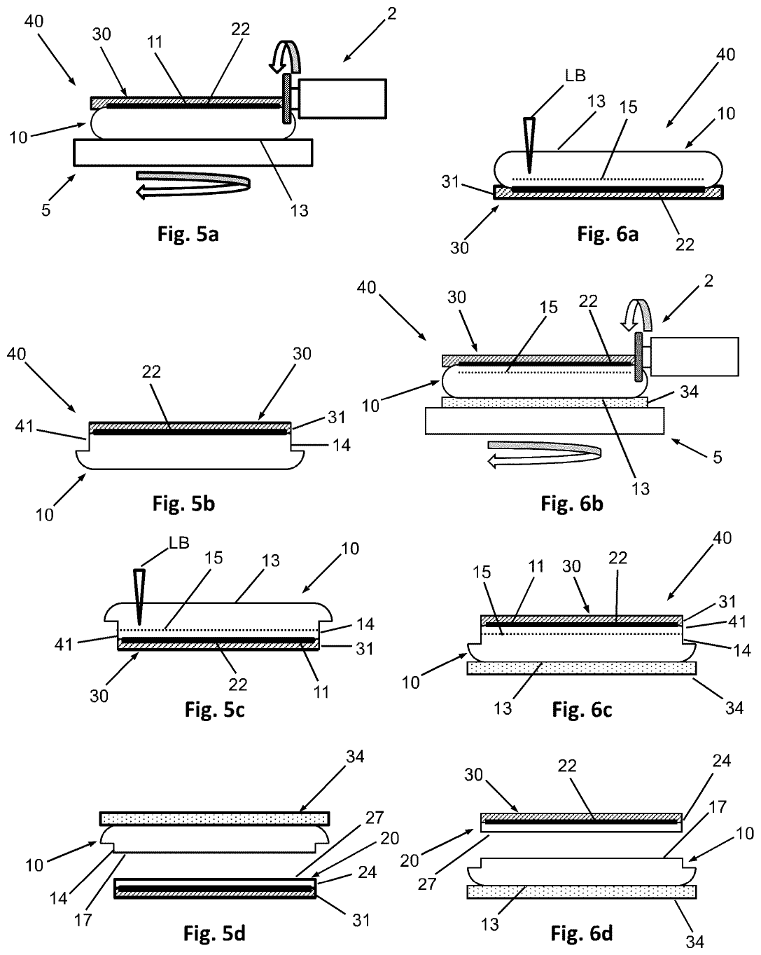

During grinding, the workpiece 40 is held by a holding table or chuck table (not shown in FIG. 4 but shown in FIG. 5a and indicated with the reference sign 5). For grinding the back side 13, the substrate 10 is held on the holding table with its front side 11 in contact with a surface of the holding table with the protective sheeting 30 arranged in between. In this respect, the protective sheeting 30 may particularly be advantageous for holding the workpiece 40 using suction by providing a flat surface. The flat surface is particularly more even than the surface of the device area 22. This enhanced flatness results in the side of the front side 11 having advantageous properties for being held by a suction force.

Turning to FIGS. 5 and 6, these figures illustrate two processing sequences according to the processing method of the present disclosure that differ from each other. These two processing sequences basically differ in the order of processing steps performed on the workpiece 40 to prepare for separating a substrate layer 20 from the substrate 10.

First turning to FIGS. 5a to 5d, the first processing sequence is explained in more detail. After applying the protective sheeting 30 (i.e., after forming the workpiece 40 and optionally grinding the back side 13 of the substrate 10), the processing sequence shown in FIGS. 5a to 5d continues as previously described with a processing step. In this processing step, a cutting device 2 processes the protective sheeting 30 and the substrate 10 from the side of the first side 11 of the substrate 10. The cutting device 2 may be a laser (ablation laser), a grinding tool (e.g., a grinding wheel), and/or a dicing tool for removing a part of the protective sheeting 30 and a part of the substrate 10.

In FIG. 5a, the cutting device 2 removes these parts of the protective sheeting 30 and the substrate 10 to form a circumferential edge 41 surrounding a central region of the front side 11 of the substrate 10 that includes the device area 22. Preferably, the cutting device 2 cuts the workpiece 40 only up to a predetermined depth of the substrate 10. In other words, the cutting device 2 does not cut fully through the substrate 10 in its thickness direction. Accordingly, the circumferential edge 41 formed during this processing step surrounds the central region of the workpiece 40 but does not extend throughout the substrate 10 (i.e., the circumferential edge 41 does not extend to the back side 13 of the substrate 10 but forms a step at the outer circumference of the workpiece 40).

The part to be removed by the cutting device 2 is located outside the central region where the device area 22 is formed and includes the protective sheeting 30 along its entire thickness and the substrate 10 along a part of its thickness. Thus, processing the workpiece 40 forms a step along the processed outer circumferential edge of the workpiece 40 that surrounds the central region of the front side 11 (see FIG. 5b). Depending on the size of the blade (e.g., a thin blade) or the laser beam (e.g., a narrow ablation laser beam), the edge trimming may be repeated multiple times to form a wider step.

In other words, the outer part to be removed extends in a transverse direction of the substrate 10 from the outer surrounding edge of the substrate 10 before processing to the location of the circumferential edge 41 created during processing that includes the protective sheeting 30 and the substrate 10. Thus, the processing step basically removes a ring-shaped outer part or section of the workpiece 40.

The circumferential edge 41 formed in this processing step includes an outer peripheral edge 14 of the substrate 10 and an outer peripheral edge 31 of the protective sheeting 30. These peripheral edges 14 and 31 are flush, surround the processed workpiece 40, and, in a thickness direction, extend partially along the workpiece 40 up to a predetermined depth of the substrate 10. This predetermined depth corresponds at least to a thickness of a substrate layer 20 to be separated from the substrate 10.

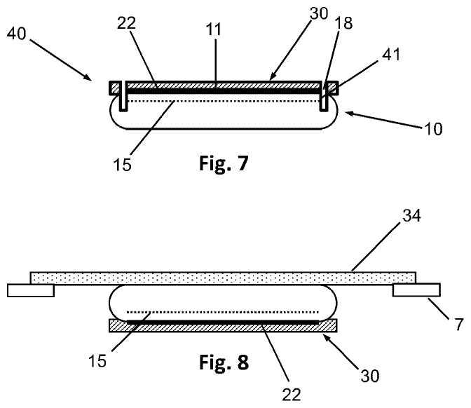

As an alternative to the processing shown in FIGS. 5a and 5b, the processing step may not remove the entire outer part of the workpiece 40 but, instead, cut a groove into the workpiece 40 that surrounds the central region where the device area 22 is formed (see FIG. 7). This results in the workpiece 40 including a ring-shaped groove 18 on the side of the front side 11 of the substrate 10, which extends through the protective sheeting 30 and into the substrate 10 up to a predetermined depth like the predetermined depth described above. The groove 18 preferably has a circular ring-shape. However, ring-shaped grooves 18 with other geometric shapes may be cut into the workpiece 40 (e.g. rectangular, polygonal, etc.).

As illustrated in FIG. 7, the groove 18 includes a first wall, a second wall, and a bottom connecting the first and second walls of the groove 18. Relative to the central region of the workpiece 40, the first wall is an inner wall facing outwards and the second wall is an outer wall facing inwards.

The first wall of the groove 18 corresponds to the circumferential edge 41 of the workpiece 40 that has been formed during the processing step. The first wall includes the protective sheeting 30 along its entire thickness and the substrate 10 along the predetermined depth which is, as previously described, less than the thickness of the substrate 10.

The second wall includes at least the substrate 10 and may further include the protective sheeting 30. The latter depends on the transverse dimension of the protective sheeting 30 that has been applied to the substrate 10. On the one hand, if the protective sheeting 30 extends in the transverse direction beyond the location of the second wall of the groove 18, the second wall includes the protective sheeting 30. On the other hand, if the protective sheeting 30 only extends in the transverse direction at maximum up to the location of the second wall, the outer part of the protective sheeting 30 is completely removed during processing when forming the groove 18. In this case, the second wall does not include the protective sheeting 30.

It is noted that the modified layer 15 in FIG. 7 may be formed before or after forming the groove 18. Thus, the technique of forming a circumferential wall 41 by creating a ring-shaped groove 18 on the side of the front side 11 of the substrate 10 applies to both the processing sequence illustrated in FIG. 5 and the processing sequence illustrated in FIG. 6.

Turning to FIG. 5c and following the processing step, a laser beam LB is applied to the substrate 10 from its back side 13. The laser beam LB has a wavelength that is transmissible through the material of the substrate 10 so that it may be focused inside the substrate 10 in a predetermined depth from the back side 13. By scanning the laser beam LB along the back side 13 of the substrate 10, in particular in a predetermined pattern, a modified layer 15 is formed inside the substrate 10. The modified layer 15 inside the substrate 10 has cracks and a reduced material strength so that the modified layer forms a separation plane that serves as origin to detach a substrate layer 20 from the substrate 10.

In a transverse direction (i.e., perpendicular to the thickness of the workpiece 40), the laser beam LB is applied inwards of the processed circumferential edge 41. Since the rounded or chamfered outer peripheral edge 14 of the substrate 10 has previously been removed, the modified layer 15 turns out to be more even. As a result, the separation surface is also more even or planar, which enhances the quality of the separation surface 17 of the substrate 10 and the separation surface 27 of the substrate layer 20 and, thus, reduces the amount postprocessing the separation surfaces 27 and 17 required to achieve a desired surface quality (e.g., grinding, polishing, etc. to remove the damages or stress and to obtain a smooth surface).

The substrate layer 20 has a predetermined thickness extending from the front side 11 of the substrate 10 to the modified layer 15. The thickness of the substrate layer 20 and, thus, the depth of the modified layer 15 from the front side 11 of the substrate 10 or the back side 13 of the substrate 10 is determined taking further processing (e.g., grinding, polishing, etc.) and the desired final thickness of the substrate layer 20 into account. In other words, the thickness of substrate layer 20 to be separated is preferably greater than the desired final thickness of the substrate layer 20 (e.g., wafer) by an amount to be removed during further processing. The desired final thickness of the substrate layer 20 after further processing may, for example, essentially correspond to the desired thickness of a singled device 21 of the device area 22 (e.g., device chips, optical devices, etc.).

Following the application of the laser beam LB and as an optional method step, a protective sheet 34 may be applied to the back side 13 of the substrate 10. Preferably, the protective sheet 34 is sized to at least cover the back side 13 of the substrate 10. In other words, the protective sheet 34 has at least a transverse dimension that corresponds to the transverse dimension of the substrate 10 (with or without the rounded or chamfered outer peripheral edge 14 of the substrate 10).

The protective sheet 34 has the advantage of protecting the surface of the back side 13. The application of the protective sheet 34 prevents damage to this surface so that the laser beam LB may be applied again (e.g., the processing method is repeated without the previously described optional grinding step) to form another modified layer 15 at a lower depth as seen from the back side 13 of the substrate 10. In this manner, the separation of another substrate layer 20 from the substrate 10 may be prepared. The step of applying a protective sheet 34 to the back side 13 of the substrate 10 is performed after applying the laser beam LB to the substrate 10 and before separating a substrate layer 20 from the substrate 10 as illustrated in FIG. 5d.

Further, the protective sheet 34 may have a size that extends beyond the outer peripheral edge 14 of the substrate 10 before processing and is attached to a ring frame 7 (see FIG. 8). The inner transverse dimension (e.g. inner diameter) of the ring frame 7 is greater than the outer transverse dimension (e.g. outer diameter) of the substrate 10 before processing (see FIG. 8). Accordingly, the substrate is centrally attached to the protective sheet 34 at a distance to the ring frame 7. The ring frame 7 particularly facilitates handling of the workpiece 14 during processing (e.g., as shown in FIG. 6b) or during separation of the substrate layer 20 from the substrate 10 at the previously formed modified layer 15 (e.g., as shown in FIGS. 5d and 6d).

FIG. 5d does not show a particular method to separate the substrate layer 20 from the substrate 10. A separation method preferably applies an external force to the wafer that generates sufficient stress in the separation plane formed by the modified layer 15 so that cracks that have been generated by applying the laser beam LB are extended further so that the substrate layer 20 and the substrate 10 may be separated from each other (i.e., they break apart). The external force may, for example, be generated by an ultrasonic irradiation unit, by wedges being inserted sideways at the level of and into the modified layer 15, and/or by pulling the substrate 10 and the substrate layer 20 away from each other.

Now turning to FIGS. 6a to 6d, an alternative processing sequence according to the present disclosure is described. In contrast to the previously described embodiment of a processing method according to the present disclosure, the processing method illustrated in FIGS. 6a to 6d applies the laser beam LB (see FIG. 6a) before processing the workpiece 40 with a cutting device 2 (see FIG. 6b). As in the previous embodiment and as described in relation to FIG. 5c, the laser beam is applied from the back side 13 of the substrate 10 and is focused in a predetermined depth to form a modified layer 15 as a weakened layer (i.e., a layer with a reduced material strength) for separating a substrate layer 20 from the substrate 10.

As illustrated in FIG. 6a, the laser beam is preferably (only) applied inwards of the section of the outer peripheral edge 14 that includes a chamfer or is rounded. Nonetheless, if it is applied to the inside of the section of the outer peripheral edge 14, it should not be applied to the outermost part of the outer peripheral edge 14. In this way, irregularities in the modified layer 15 are at least reduced and an undesired premature substrate layer separation that might be caused by the edge trimming process (in particular when using a dicing blade) can be prevented. Applying the laser beam LB in the predetermined depth in a transverse direction except for the rounded or chamfered circumferential portion of the substrate 10 also reduces processing time.

Following the application of the laser beam LB, the next step is a processing step that is basically performed as previously described under reference to FIG. 5a. In particular, a cutting device 2 processes the substrate 10 from the front side 11.

Further, when processing the workpiece 40, a protective sheet 34 as previously described, may be optionally attached to the back side 13 of the substrate 10. As described above, the protective sheet 34 protects the surface of the substrate 10 on the side of the back side 13 from being contaminated or damaged and may further enhance the fixation of the workpiece 40 to the holding table 5, in particular if a suction force is used as means to hold the workpiece 40 with the holding table 5.

As further illustrated in FIG. 5a (also see FIG. 6b), the cutting device 2 (in particular a cutting or grinding tool thereof) may be turned to machine the circumferential edge 41 of the workpiece by removing material from the protective sheeting 30 and the substrate 10. However, it should be noted that in case of the cutting device 2 applying a laser beam to process the workpiece 40, such a rotation is not necessary. Nonetheless, in both cases the holding table 5 is preferably rotated for processing the (entire) circumference of the workpiece 40 while keeping the cutting device at the same location.

As previously described, the modified layer 15 is already formed when machining the outer peripheral edge 14 of the substrate 10. Accordingly, machining the outer peripheral edge 14 of the substrate 10 will also provide a more uniform or even modified layer 15 due to removal of the chamfered or rounded portion of the outer peripheral edge 14 of the substrate 10. It is particularly advantageous that a protective sheet 34 may be used during processing, which may further remain attached to the substrate during the remainder of the method steps to protect the back side 13 of the substrate 10 from being contaminated or damaged.

The resulting configuration of the workpiece 40 is illustrated in FIG. 6c. This figure illustrates the workpiece 40 including the optional protective sheet 34 attached to the back side 13 of the substrate 10 and the protective sheeting 30 that remains attached to the front side 11 of the substrate 10 to protect the device area 22 from being contaminated.

The processed circumferential edge 41 of the workpiece 40 is configured as described above. More specifically, the processed circumferential edge 41 may be formed as a step, wherein the surface of the processed circumferential edge 41 (forming the portion of this step in the thickness direction) includes an outer peripheral edge 31 of the protective sheeting 30 extending along the entire thickness of the protective sheeting 30 and an outer peripheral edge 14 of the substrate 10 that partially extends along the thickness of the substrate 10. The surface of the outer peripheral edge 31 and the surface of the outer peripheral edge 14 are flush with each other.

As illustrated in FIG. 6d, the configuration of the workpiece 40 after processing allows to separate the substrate layer 20 from the substrate 10, wherein the substrate layer 20 has a comparatively dull outer peripheral edge 24 that comprises the outer peripheral edge 31 of the protective sheeting 30 and a part of the outer peripheral edge 14 of the substrate 10 that has been processed in the previous processing step.

Since the modified layer 15 is produced with an enhanced uniformity, the separation surface 17 of the substrate 10 and/or the separation surface 27 of the substrate layer 20 also tend to have an enhanced flatness so that the amount of postprocessing may be lowered for achieving the desired surface properties.

For example, the surface properties of the separation surface 27 of the substrate layer 20 may be chosen in view of increasing the strength (die break strength) of the single devices 21 after dicing the device area in a subsequent processing step (not shown). On the other hand, the separation surface 17 of the substrate 10 may be machined to a degree so that another device area 22 may be formed on the separation surface 17 which will then represent a new front side 11 of the substrate 10.

t is noted that in case of producing multiple substrate layers 20 with device areas 22 formed thereon from a single substrate 10, the circumferential edge 41 of the workpiece 40 may be created by performing above-described manufacturing steps only once. Differently said, the length of the circumferential edge 41 in the thickness direction of the substrate 10 may be formed at once by the cutting device 2.

1. A substrate processing method for processing a substrate having a front side and a back side, wherein a device area is formed on the front side of the substrate, the method comprising:
applying a protective sheeting to the front side of the substrate,
processing the protective sheeting and the substrate from the front side using a cutting device to form a circumferential edge, wherein at the circumferential edge the processed protective sheeting and the processed substrate are flush in a thickness direction of the substrate, and
applying a laser beam from the back side of the substrate to form a modified layer inside the substrate in a predetermined depth.

2. The substrate processing method according to claim 1, wherein
the circumferential edge extends partially in a thickness direction of the substrate along a distance of at least a thickness of a substrate layer to be separated from the substrate.

3. The substrate processing method according to claim 1, wherein
processing the protective sheeting includes removing an outer part of the processed protective sheeting and the substrate so that the circumferential edge forms an outer peripheral edge of the protective sheeting and an outer peripheral edge of the substrate.

4. The substrate processing method according to claim 1, wherein
processing the protective sheeting includes cutting a groove into the substrate to form the circumferential edge.

5. The substrate processing method according to claim 1, wherein the laser beam is only applied in a central region of the substrate having essentially a uniform thickness.

6. The substrate processing method according to claim 1, wherein the laser beam is applied before or after processing the protective sheeting and the substrate.

7. The substrate processing method according to claim 1, wherein the method further comprises pre-grinding the back side of the substrate before applying the laser beam.

8. The substrate processing method according to claim 1, wherein the method further comprises separating the substrate layer from the substrate at the modified layer and preferably grinding the separation surface of the substrate and/or the separation surface of the substrate layer.

9. The substrate processing method according to claim 1, wherein the method further comprises mounting a protective sheet to the back side of the substrate after forming the modified layer inside the substrate.

10. The substrate processing method according to claim 9, wherein the protective sheet is larger than the back side of the substrate and is attached to a ring frame surrounding the peripheral edge of the substrate at a distance.

11. The substrate processing method according to claim 1, wherein the substrate is a wafer.

12. The substrate processing method according to claim 1, wherein the protective sheeting is applied with h the protective sheeting and the front side of the substrate being free of an adhesive at least in a central surface region thereof.

13. The substrate processing method according claim 1, wherein the protective sheeting is applied using an adhesive at least in a peripheral marginal area of the front side of the substrate.
